(19) United States
(12) Patent Application Publication
(10) Pub. No.: US 2015/0084078 A1
(43) Pub. Date: Mar. 26, 2015

(54) Light-Emitting Diode Having Diamond-Like Carbon Layer and Manufacturing Method and Application Thereof

(71) Applicant: Chien-Min Sung, Tansui (TW)

(72) Inventor: Chien-Min Sung, Tansui (TW)

(21) Appl. No.: 14/223,527

(22) Filed: Mar. 24, 2014

Related U.S. Application Data
(63) Continuation of application No. 14/145,758, filed on Dec. 31, 2013, now abandoned.
Application No. 14/145,758 is a continuation of application No. 14/052,934, filed on Oct. 14, 2013, now abandoned.
Application No. 14/052,934 is a continuation of application No. 13/950,037, filed on Jul. 24, 2013, now abandoned.

(51) Int. Cl. H01L 33/64; H01L 33/56; H01L 33/16; H01L 33/60

(52) U.S. Cl. CPC H01L 33/641; H01L 33/60; H01L 33/56; H01L 33/16
USPC 257/98; 257/99; 438/26; 438/27

(57) ABSTRACT

A light emitting diode having a diamond-like carbon layer is disclosed, which includes: a substrate; a semiconductor epitaxial multilayer structure deposited over the substrate and including a first semiconductor epitaxial layer and a second semiconductor epitaxial layer, wherein the first and second semiconductor epitaxial layers are stacked with each other; an insulating diamond-like carbon covering partial surface of the semiconductor epitaxial multilayer structure; a first electrode provided with an electrical connection to the first semiconductor epitaxial layer; and a second electrode provided with an electrical connection to the second semiconductor epitaxial layer. A manufacturing method and application of the light-emitting diode are also disclosed.

### PRIORITY DATA

This application is a continuation of U.S. patent application Ser. No. 14/145,758, filed Dec. 31, 2013, which is a continuation of U.S. patent application Ser. No. 14/052,934, filed Oct. 14, 2013, which is a continuation of U.S. patent application Ser. No. 13/950,037, filed Jul. 24, 2013, each of which are incorporated herein by reference.

### BACKGROUND OF THE INVENTION

1. Field of the Invention

The present invention relates to a light emitting diode and a manufacturing method and application thereof, more particularly, to a light emitting diode having a diamond-like carbon layer, a method of manufacturing the same, and a chip-on-board package structure comprising the same.

2. Description of Related Art

Since the 1960s, light emitting diodes (LEDs) are progressively taking the place of traditional lighting lamps, indicator lamps of electrical devices or other light sources due to their benefits such as low power consumption and long duration time. Moreover, the development of multicolor LEDs with high brightness has contributed to their application in large outdoor display boards or traffic light.

LEDs include two electrodes disposed on the same side of a chip (i.e. lateral LEDs) or on the opposite sides of a chip (i.e. vertical LEDs). In lateral LEDs, current takes a turn past a semiconductor light emitting layer and then flows along a horizontal direction of the chip. Unlike lateral LEDs, current in vertical LEDs can flow between two electrodes without turning phenomenon.

As shown in FIG. 1, a conventional lateral light emitting diode includes a semiconductor epitaxial layer 14, a first electrode 12, a second electrode 16 and an encapsulant 18. The semiconductor epitaxial multilayer structure 14 includes a first semiconductor epitaxial layer 141, an active layer 142 and a second semiconductor epitaxial layer 143, and the encapsulant 18 is used as a packaging material and is disposed on the semiconductor epitaxial layer 14, the first electrode 12 and the second electrode 16 to protect the final product.

However, when the encapsulant 18 is directly disposed on the semiconductor epitaxial layer 14, the first electrode 12 and the second electrode 16, the poor adhesion between the encapsulant 18 and the semiconductor epitaxial layer 14 may cause deterioration of heat dissipation of the whole LED. Besides, since LEDs have large mismatch in coefficient of thermal expansion (CTE) among layers in LEDs, the rise of temperature caused by the heat accumulation in LEDs may easily induce the expansion and deformation of LEDs, resulting in the reduction of luminous efficiency and lifetime of LEDs. In particular, when the LED is further packaged on a circuit board, thermal expansion may result in breakage, short circuit or failure of electrical connections due to CTE mismatch between the circuit board and the LED.

Therefore, it is desirable to develop new LED technology to enhance heat dissipation and thus to improve luminous efficiency and lifetime of LEDs.

### SUMMARY OF THE INVENTION

In one aspect of the present invention is to provide a light emitting diode having a diamond-like carbon layer, in which the thermal expansion stress among layers in the LED can be released by the provision of diamond-like carbon layers, for example, disposing a conductive diamond-like carbon layer as an electrode and applying an insulating diamond-like carbon layer to protect the semiconductor epitaxial multilayer structure, so as to improve heat dissipation of the whole LED and thus to enhance the LED luminous lifetime.

To achieve the object, one aspect of the present invention provides a light emitting diode having a diamond-like carbon layer, which includes: a substrate; a semiconductor epitaxial multilayer structure that is disposed over the substrate and includes a first semiconductor epitaxial layer and a second semiconductor epitaxial layer, wherein the first semiconductor epitaxial layer and the second semiconductor epitaxial layer are disposed in a laminated state; an insulating diamond-like carbon layer that covers partial surfaces of the semiconductor epitaxial multilayer structure; a first electrode that is electrically connected to the first semiconductor epitaxial layer of the semiconductor epitaxial multilayer structure; and a second electrode that is electrically connected to the second semiconductor epitaxial layer of the semiconductor epitaxial multilayer structure.

In general, silicon dioxide is applied in conventional LEDs to provide electrical isolation for the semiconductor epitaxial multilayer structure. However, since silicon dioxide has a low thermal conductivity (about 1.4 W/mK), heat generated during LED operation cannot be timely dissipated and thus accumulated in LEDs. Accordingly, the long-term operation of LEDs will cause serious deterioration of LED luminous efficiency and shortening of LED lifetime.

Unlike the conventional art, the LED having a diamond-like carbon layer according to the present invention uses an insulating diamond-like carbon layer to provide electrical isolation for the semiconductor epitaxial multilayer structure. Due to high thermal conductivity (about 475 W/mK) of diamond-like carbon, the insulating diamond-like carbon layer, which is disposed on either or both of partial surfaces and side walls of the semiconductor epitaxial multilayer structure, can enhance heat dissipation, luminous efficiency and lifetime of the LED. Moreover, since the insulating diamond-like carbon layer has electrical resistivity and dielectric constant similar to silicon dioxide, the insulating diamond-like carbon layer can provide electrical insulation for the semiconductor epitaxial multilayer structure to protect the semiconductor epitaxial multilayer structure from short circuit or current leakage.

In the above LED having a diamond-like carbon layer according to the present invention, the semiconductor epitaxial multilayer structure can further include: an active layer that is sandwiched between the first semiconductor epitaxial layer and the second semiconductor epitaxial layer. In the present invention, the active layer may be a multiple quantum well layer to enhance LED's conversion efficiency from electricity to light.

In one preferred embodiment of the present invention, the LED having a diamond-like carbon layer is a vertical LED, in which the first electrode can be disposed between the substrate and the semiconductor epitaxial multilayer structure and cover the insulating diamond-like carbon layer from the substrate side, such that the insulating diamond-like carbon layer is sandwiched between the semiconductor epitaxial multilayer structure and the first electrode. Besides, the LED having a diamond-like carbon layer can further selectively include a reflective layer that can be disposed between the first electrode and the semiconductor epitaxial multilayer structure. The material of the reflective layer may be aluminum, silver, nickel (Ni), cobalt (Co), palladium (Pd), platinum (Pt), gold (Au), zinc (Zn), tin (Sn), antimony (Sb), lead (Pb), copper (Cu), copper-silver (CuAg), nickel-silver (NiAg), an alloy thereof or a metal mixture thereof.

However, the LED having a diamond-like carbon layer according to the present invention is not limited to a vertical LED, and may be a lateral LED or be further manufactured into a flip-chip type LED. Specifically, the lateral LED can use conductive diamond-like carbon as the material of the corresponding electrode for the p-type semiconductor epitaxial layer, and the flip-chip type LED, which is similar to the lateral LED, can further apply conductive diamond-like carbon on the surface of the corresponding electrode for the n-type semiconductor epitaxial layer to make the surface of the corresponding electrode for the n-type semiconductor epitaxial layer coplanar with the surface of the corresponding electrode for the p-type semiconductor epitaxial layer. Moreover, the side walls and/or exposed surfaces of the semiconductor epitaxial multilayer structure can be covered by an insulating passivation layer, regardless of the LED having a diamond-like carbon layer according to the present invention being a vertical LED, a lateral LED or a flip-chip type LED.

Preferably, the first semiconductor epitaxial layer and the first electrode are p-type, the second semiconductor epitaxial layer and the second electrode are n-type, and the first electrode is made of conductive diamond-like carbon. Herein, the conductive diamond-like carbon may be a DLC/metal multilayer composite, a metal-containing DLC mixture or graphitized DLC. The metal can be titanium (Ti), tungsten (W), chromium (Cr), molybdenum (Mo), an alloy thereof or a metal mixture or alloy thereof. The application of the conductive diamond-like carbon in the electrode can reduce the influence of thermal expansion on the LED structure due to its better coefficient of thermal expansion (CTE), enhance heat dissipation during LED operation and reduce the possibility of heat-induced damage to the LED structure.

In the LED having a diamond-like carbon layer according to the present invention, the substrate can be made of a conductive material. The conductive material may be metal, a mixture of metal and ceramic or a mixture of metal and diamond.

Additionally, another object of the present invention is to provide a method of fabricating a light emitting diode having a conductive diamond-like carbon layer, in which a continuous-layered conductive diamond-like carbon layer is used as a corresponding electrode for the p-type semiconductor epitaxial layer of the semiconductor epitaxial multilayer structure and an insulating diamond-like carbon layer is applied as a passivation layer of the semiconductor epitaxial multilayer structure so as to enhance heat dissipation of the LED.

To achieve the above object, another aspect of the present invention provides a method of fabricating a light emitting diode having a conductive diamond-like carbon layer, which includes the following steps: providing a temporary substrate; forming a semiconductor epitaxial multilayer structure on the temporary substrate, wherein the semiconductor epitaxial multilayer structure includes a first semiconductor epitaxial layer and a second semiconductor epitaxial layer, and the first semiconductor epitaxial layer and the second semiconductor epitaxial layer are disposed in a laminated state; forming an insulating diamond-like carbon layer on side walls of the semiconductor epitaxial multilayer structure; and forming a first electrode and a second electrode and removing the temporary substrate, wherein the first electrode is electrically connected to the first semiconductor epitaxial layer of the semiconductor epitaxial multilayer structure, and the second electrode is electrically connected to the second semiconductor epitaxial layer of the semiconductor epitaxial multilayer structure.

In the above method of fabricating an LED having a conductive diamond-like carbon layer according to the present invention, the steps can be executed with the sequence set forth above, but it is also possible to reorder the sequence of the steps or simultaneously execute some steps according to desired design. For example, in the case of making a vertical LED, after the semiconductor epitaxial multilayer structure, the insulating diamond-like carbon layer, the first electrode and the substrate are formed on the temporary substrate in sequence, the step of forming the second electrode is executed after removing the temporary substrate. In the case of making a lateral LED or a flip-chip type LED, the semiconductor epitaxial multilayer structure, the insulating diamond-like carbon layer, the first electrode and the second electrode are formed on the substrate in sequence, or the first electrode and the second electrode are simultaneously formed. Moreover, the method of fabricating a flip-chip type LED can further include a step of thickening the second electrode to make the surface of the second electrode coplanar with the surface of the first electrode.

On the other hand, in the above method of fabricating an LED having a conductive diamond-like carbon layer according to the present invention, the insulating diamond-like carbon layer is used to provide electrical insulation for the semiconductor epitaxial multilayer structure. As the electrical resistivity and dielectric constant of diamond-like carbon are similar to commonly used silicon oxide, the insulating diamond-like carbon layer can provide electrical insulation for the semiconductor epitaxial multilayer structure to protect the semiconductor epitaxial multilayer structure from short circuit or current leakage, and even can enhance thermal performance, luminous efficiency and lifetime of LEDs due to its higher thermal conductivity compared to silicon dioxide.

In the above method of fabricating an LED having a conductive diamond-like carbon layer according to the present invention, the semiconductor epitaxial multilayer structure can selectively further include an active layer disposed between the first semiconductor epitaxial layer and the second semiconductor epitaxial layer.

The above method of fabricating an LED having a conductive diamond-like carbon layer according to the present invention can selectively further include the following step: forming a reflective layer on the surface of the first semiconductor epitaxial layer after forming the semiconductor epitaxial multilayer structure. The material of the reflective layer may be Al, Ag, Ni, Co, Pd, Pt, Au, Zn, Sn, Sb, Pb, Cu, CuAg, NiAg, an alloy thereof or a metal mixture thereof. Besides, the first semiconductor epitaxial layer and the first electrode can be p-type, the second semiconductor epitaxial layer and the second electrode can be n-type, and the first electrode can be made of conductive diamond-like carbon. Herein, the conductive diamond-like carbon may be a DLC/metal multilayer composite, a metal-containing DLC mixture or graphitized DLC. The metal can be Ti, W, Cr, Mo, an alloy thereof or a metal mixture thereof.

Moreover, the above method of fabricating an LED having a conductive diamond-like carbon layer according to the present invention can selectively further include the following step: roughening the surface of the second semiconductor epitaxial layer of the semiconductor epitaxial multilayer structure after removing the temporary substrate.

Furthermore, yet another object of the present invention is to provide a chip-on-board (COB) package structure with the above LED having a conductive diamond-like carbon layer according to present invention electrically connected to a circuit board by flip-chip or wire-bonding connection. Accordingly, the diamond-like carbon layer in this structure can release the thermal expansion stress among layers of the LED structure, and the chip-on-board (COB) package structure can exhibit improved thermal performance, luminous efficiency and lifetime.

To achieve the above object, yet another aspect of the present invention provides a chip-on-board (COB) package structure, which includes: a circuit board; and the above LED having a conductive diamond-like carbon layer according to present invention that is electrically connected to the circuit board through the first electrode and the second electrode.

In the above COB package structure of the present invention, the circuit board can include an insulating layer and a circuit substrate. The material of the insulating layer can be insulating diamond-like carbon, aluminum oxide, ceramics, a diamond-containing epoxy resin or a combination thereof or a metal coated with the above insulating layer on its surface. The circuit substrate may be a metal sheet, a ceramic sheet or a silicon substrate. In addition, the circuit substrate can selectively further include a diamond-like carbon layer on a surface thereof to enhance the thermal performance.

### BRIEF DESCRIPTION OF THE DRAWINGS

FIG. 1 shows a schematic view of a conventional lateral light emitting diode;

FIGS. 2A to 2I show a process of fabricating a light emitting diode having a conductive DLC layer according to Example 1 of the present invention; and

FIG. 3 shows a schematic view of a chip-on-board package structure according to Example 2 of the present invention.

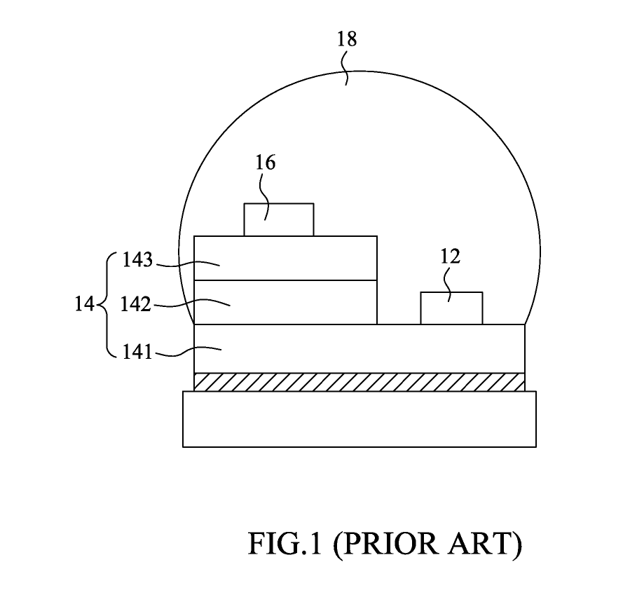

### DETAILED DESCRIPTION OF THE PREFERRED EMBODIMENT

Hereafter, examples will be provided to illustrate the embodiments of the present invention. Other advantages and effects of the invention will become more apparent from the disclosure of the present invention. Other various aspects also may be practiced or applied in the invention, and various modifications and variations can be made without departing from the spirit of the invention based on various concepts and applications.

It should be noted that these accompanying figures are simplified and only show components related to the present invention. The quantity, shape and size of components shown in the figures may be modified according to practically conditions, and the arrangement of components may be more complex.

### Example 1

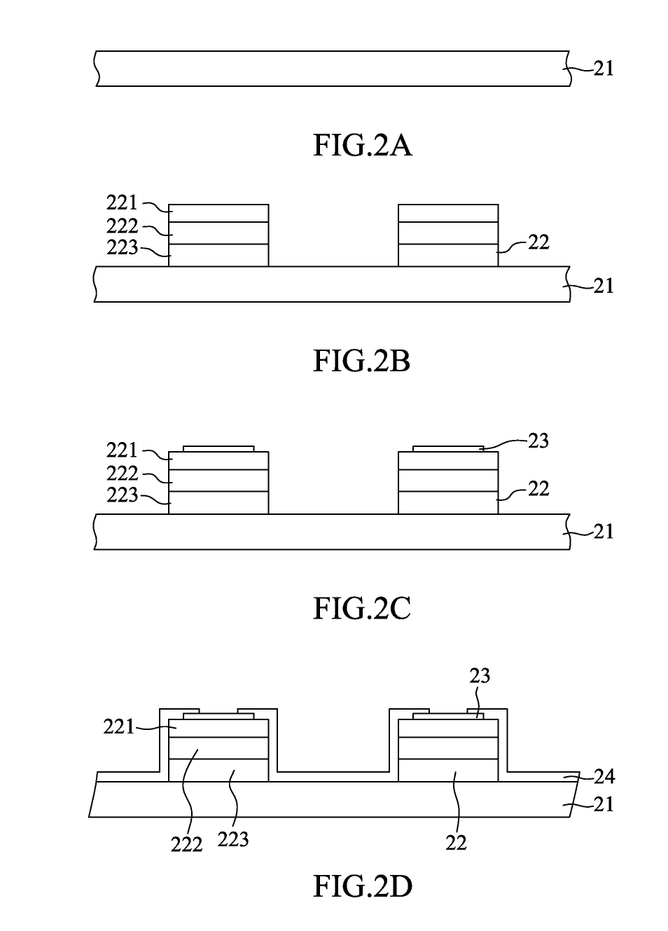

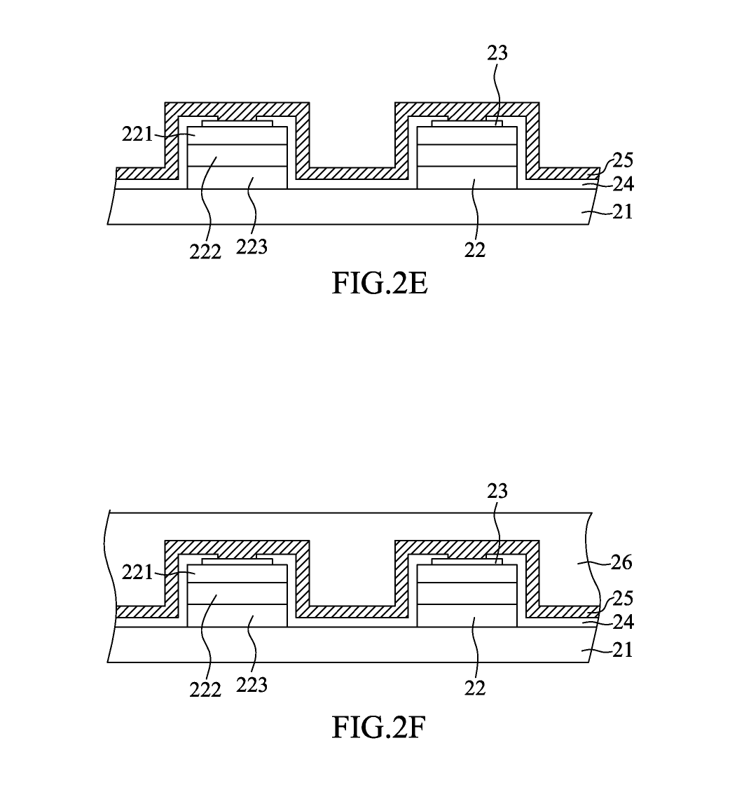

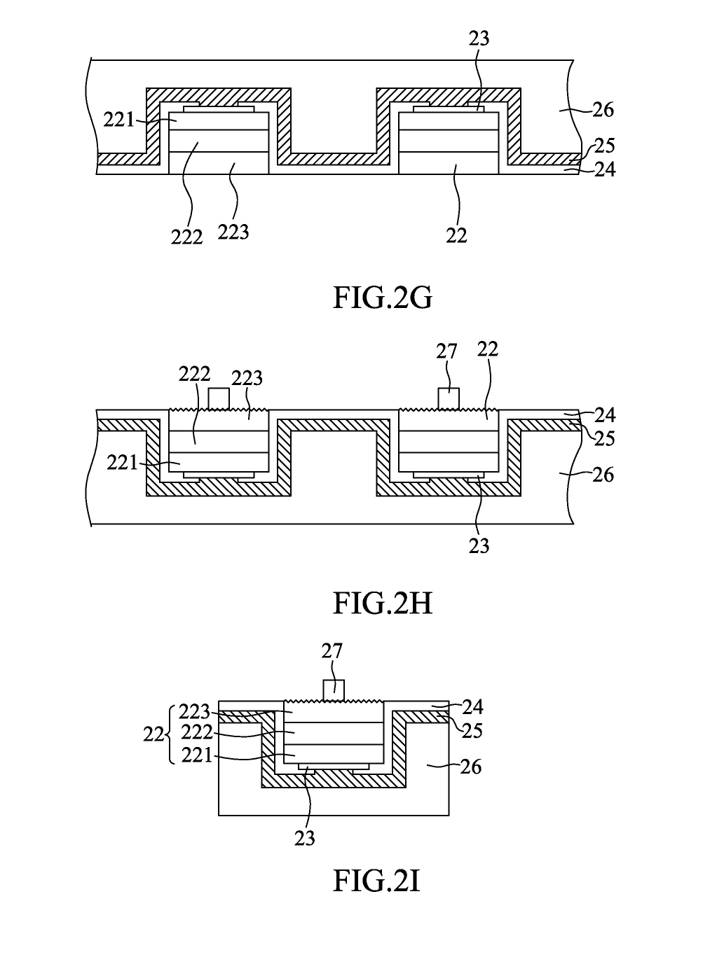

FIGS. 2A-2I show a method of fabricating a light emitting diode having a conductive diamond-like carbon layer according to the present invention.

First, as shown in FIG. 2A, a temporary substrate 21 is provided. Then, as shown in FIG. 2B, a semiconductor epitaxial multilayer structure 22 is formed on the temporary substrate 21. The semiconductor epitaxial multilayer structure 22 can include a first semiconductor epitaxial layer 221, an active layer 222 and a second semiconductor epitaxial layer 223. Herein, the first semiconductor epitaxial layer 221, the active layer 222 and the second semiconductor epitaxial layer 223 are disposed in a laminated state, and the active layer 222 is sandwiched between the first semiconductor epitaxial layer 221 and the second semiconductor epitaxial layer 223. In this example, the semiconductor epitaxial multilayer structure 22 is made of gallium nitride (GaN). However, in the present invention, the suitable material of the semiconductor epitaxial multilayer structure is not limited thereto, and may be any material commonly used in this art. Additionally, the active layer can be optionally applied according to requirement. In this example, the active layer is a multiple quantum well layer to enhance LED's conversion efficiency from electricity to light.

Subsequently, as shown in FIG. 2C, a reflective layer 23 is formed on the surface of the first semiconductor epitaxial layer 221 of the semiconductor epitaxial multilayer structure 22. As shown in FIG. 2D, an insulating diamond-like carbon layer 24 is then formed to cover the lateral surface of the semiconductor epitaxial multilayer structure 22, the partial surface of the first semiconductor epitaxial layer 221, the partial surface of the reflective layer 23, and the partial surface of the temporary substrate 21. Herein, the insulating diamond-like carbon layer 24 has openings to expose the reflective layer 23. In this example, the material of the reflective layer 23 can be at least one selected from the group consisting of aluminum, silver, nickel (Ni), cobalt (Co), palladium (Pd), platinum (Pt), gold (Au), zinc (Zn), tin (Sn), antimony (Sb), lead (Pb), copper (Cu), copper-silver (CuAg) and nickel-silver (NiAg). One person having ordinary knowledge in this art can clearly understand that the step of forming the reflective layer as shown in FIG. 2C can be selectively executed according to requirement. That is, the step illustrated in FIG. 2C can be omitted if no intend to dispose the reflective layer.

As shown in FIG. 2E, a first electrode 25 is formed to fill the openings of the insulating diamond-like carbon layer 24 and to cover the exposed surfaces of the diamond-like carbon layer 24 and the reflective layer 23. Accordingly, the first electrode 25 is electrically connected to the first semiconductor epitaxial layer 221 of the semiconductor epitaxial multilayer structure 22. In this example, the first electrode 25 is made of conductive diamond-like carbon. Herein, the conductive diamond-like carbon may be a DLC/metal multilayer composite, a metal-containing DLC mixture or graphitized DLC. The DLC/metal multilayer composite means a laminate of a DLC layer and a metal layer or a laminate of a DLC and multiple metal layers. The metal may be at least one selected from the group consisting of titanium (Ti), tungsten (W), chromium (Cr) and molybdenum (Mo).

Next, as shown in FIG. 2F, a substrate 26 is formed on the first electrode 25. In this example, the material of the substrate 11 may be metal, ceramics (e.g. MN, SiO₂, Al₂O₃ etc.), glass, sapphire, diamond or a mixture of the above-mentioned materials. The metal substrate may be, for example, a copper plating substrate, copper/nickel cobalt/copper plating substrate, copper/nickel cobalt alloy multilayer metal sheet, or copper/nickel cobalt composite material substrate doped with diamond in each layer.

As shown in FIG. 2G, the temporary substrate 21 is removed from the second semiconductor epitaxial layer 223 of the semiconductor epitaxial multilayer structure 22 and the surface of the insulating diamond-like carbon layer 24. Then, as shown in FIG. 2H, the surface of the second semiconductor epitaxial layer 223 of the semiconductor epitaxial multilayer structure 22 is roughened, followed by forming a second electrode 27 on the surface of the second semiconductor epitaxial layer 223 of the semiconductor epitaxial multilayer structure 22. Finally, as shown in FIG. 2I, a single LED is separated by a cutting process. In this example, the second electrode 27 may be made of a material similar to that applied in the first electrode (i.e. conductive DLC). However, any electrode material commonly used in this art also can be applied therein. Besides, the first semiconductor epitaxial layer 221 and the first electrode 25 are p-type, and the second semiconductor epitaxial layer 223 and the second electrode 27 are n-type.

Accordingly, as shown in FIG. 2I, the light emitting diode having aluminum nitride layers includes: a substrate 26; a semiconductor epitaxial multilayer structure 22 that is disposed over the substrate 26 and includes a first semiconductor epitaxial layer 221, an active layer 222 and a second semiconductor epitaxial layer 223, wherein the first semiconductor epitaxial layer 221, the active layer 222 and the second semiconductor epitaxial layer 223 are disposed in a laminated state, and the active layer 222 is sandwiched between the first semiconductor epitaxial layer 221 and the second semiconductor epitaxial layer 223; an insulating diamond-like carbon layer 24 that covers partial surfaces of the semiconductor epitaxial multilayer structure 22; a first electrode 25 that covers the insulating diamond-like carbon layer 24 and is disposed between the substrate 26 and the semiconductor epitaxial multilayer structure 22 and is electrically connected to the first semiconductor epitaxial layer 221 of the semiconductor epitaxial multilayer structure 22; a reflective layer 23 that is disposed between the first electrode 25 and the semiconductor epitaxial multilayer structure 22; and a second electrode 27 that is electrically connected to the second semiconductor epitaxial layer 223 of the semiconductor epitaxial multilayer structure 22. Herein, the insulating diamond-like carbon layer 24 is sandwiched between the semiconductor epitaxial multilayer structure 22 and the first electrode 25.

As above mentioned, the present invention applies diamond-like carbon layers in the light emitting diode (such as the continuous-layered conductive diamond-like carbon layer as a corresponding electrode for the p-type semiconductor epitaxial layer of the semiconductor epitaxial multilayer structure, the insulating diamond-like carbon layer as a passivation layer of the semiconductor epitaxial multilayer structure) so as to release thermal expansion stress among layers in the LED and improve the heat dissipation efficiency of the LED, resulting in the enhancement of the LED lifetime.

### Example 2

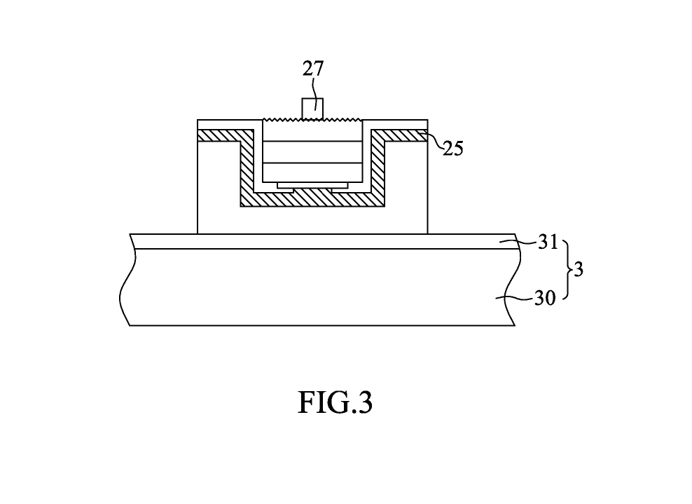

FIG. 3 shows a schematic view of a chip-on-board (COB) package structure according to this example.

As shown in FIG. 3, the chip-on-board package structure includes: a circuit board 3; and a light emitting diode having a conductive diamond-like carbon layer, which is manufactured by the method illustrated in Example 1 and electrically connected to the circuit board 3 through the first electrode 25 and the second electrode 27. Herein, the circuit board 3 includes an insulating layer 31, a circuit substrate 20 and wiring (not shown in the figure). The material of the insulating layer 31 can be selected from diamond-like carbon (DLC), aluminum oxide, ceramics, a diamond-containing epoxy resin or a mixture of the above materials. The circuit substrate 30 may be a metal sheet, a ceramic sheet or a silicon substrate.

In the COB package structure, the first electrode 25 and the second electrode 27 can be electrically connected to the circuit board 3 by an ordinary technology known in this art, such as wire bonding.

Accordingly, in the above-mentioned COB package structure of the present invention, the thermal expansion stress among layers of the LED can be released by the diamond-like carbon layers in this structure, such that the whole COB package structure can have improved thermal performance, luminous efficiency and lifetime.

The above examples are intended for illustrating the embodiments of the present invention. The scope of the present invention is based on the claims as appended and is not limited to the above examples.

What is claimed is:

1. A light emitting diode having a diamond-like carbon layer, comprising:
a substrate;
a semiconductor epitaxial multilayer structure, disposed over the substrate and comprising a first semiconductor epitaxial layer and a second semiconductor epitaxial layer, wherein the first semiconductor epitaxial layer and the second semiconductor epitaxial layer are disposed in a laminated state;
an insulating diamond-like carbon layer, covering partial surfaces of the semiconductor epitaxial multilayer structure;
a first electrode, electrically connected to the first semiconductor epitaxial layer of the semiconductor epitaxial multilayer structure; and
a second electrode, electrically connected to the second semiconductor epitaxial layer of the semiconductor epitaxial multilayer structure.

2. The light emitting diode having a diamond-like carbon layer as claimed in claim 1, wherein the semiconductor epitaxial multilayer structure further comprises:
an active layer that is sandwiched between the first semiconductor epitaxial layer and the second semiconductor epitaxial layer.

3. The light emitting diode having a diamond-like carbon layer as claimed in claim 1, wherein the first electrode covers the insulating diamond-like carbon layer and is disposed between the substrate and the semiconductor epitaxial multilayer structure.

4. The light emitting diode having a diamond-like carbon layer as claimed in claim 3, wherein the insulating diamond-like carbon layer is disposed between the semiconductor epitaxial multilayer structure and the first electrode.

5. The light emitting diode having a diamond-like carbon layer as claimed in claim 1, wherein the first semiconductor epitaxial layer and the first electrode are p-type, and the second semiconductor epitaxial layer and the second electrode are n-type.

6. The light emitting diode having a diamond-like carbon layer as claimed in claim 1, wherein the first electrode is made of a conductive diamond-like carbon.

7. The light emitting diode having a diamond-like carbon layer as claimed in claim 6, wherein the conductive diamond-like carbon is a DLC/metal multilayer composite, a metal-containing DLC mixture or graphitized DLC.

8. The light emitting diode having a diamond-like carbon layer as claimed in claim 7, wherein the metal is at least one selected from the group consisting of titanium (Ti), tungsten (W), chromium (Cr) and molybdenum (Mo).

9. The light emitting diode having a diamond-like carbon layer as claimed in claim 1, wherein the material of the substrate is metal, a mixture of metal and ceramic, or a mixture of metal and diamond.

10. The light emitting diode having a diamond-like carbon layer as claimed in claim 1, further comprising a reflective layer that is disposed between the first electrode and the semiconductor epitaxial multilayer structure.

11. The light emitting diode having a diamond-like carbon layer as claimed in claim 10, wherein the material of the reflective layer is at least one selected from the group consisting of aluminum, silver, nickel (Ni), cobalt (Co), palladium (Pd), platinum (Pt), gold (Au), zinc (Zn), tin (Sn), antimony (Sb), lead (Pb), copper (Cu), copper-silver (CuAg) and nickel-silver (NiAg).

12. A method of manufacturing a light emitting diode having a conductive diamond-like carbon layer, comprising steps:
providing a temporary substrate;
forming a semiconductor epitaxial multilayer structure on the temporary substrate, wherein the semiconductor epitaxial multilayer structure comprises a first semiconductor epitaxial layer and a second semiconductor epitaxial layer, and the first semiconductor epitaxial layer and the second semiconductor epitaxial layer are disposed in a laminated state;
forming an insulating diamond-like carbon layer on side walls of the semiconductor epitaxial multilayer structure; and
forming a first electrode in electrical connection with the first semiconductor epitaxial layer of the semiconductor epitaxial multilayer structure, forming a second electrode in electrical connection with the second semiconductor epitaxial layer of the semiconductor epitaxial multilayer structure, and removing the temporary substrate.

13. The method of manufacturing a light emitting diode having a conductive diamond-like carbon layer as claimed in claim 12, wherein the semiconductor epitaxial multilayer structure further comprises: an active layer that is sandwiched between the first semiconductor epitaxial layer and the second semiconductor epitaxial layer.

14. The method of manufacturing a light emitting diode having a conductive diamond-like carbon layer as claimed in claim 12, further comprising a step: forming a reflective layer on a surface of the first semiconductor epitaxial layer of the semiconductor epitaxial multilayer structure after forming the semiconductor epitaxial multilayer structure.

15. The method of manufacturing a light emitting diode having a conductive diamond-like carbon layer as claimed in claim 12, wherein the first semiconductor epitaxial layer and the first electrode are p-type, and the second semiconductor epitaxial layer and the second electrode are n-type.

16. The method of manufacturing a light emitting diode having a conductive diamond-like carbon layer as claimed in claim 12, wherein the first electrode is made of a conductive diamond-like carbon.

17. The method of manufacturing a light emitting diode having a conductive diamond-like carbon layer as claimed in claim 16, wherein the conductive diamond-like carbon is a DLC/metal multilayer composite, a metal-containing DLC mixture or graphitized DLC.

18. The method of manufacturing a light emitting diode having a conductive diamond-like carbon layer as claimed in claim 17, wherein the metal is at least one selected from the group consisting of titanium (Ti), tungsten (W), chromium (Cr) and molybdenum (Mo).

19. The method of manufacturing a light emitting diode having a conductive diamond-like carbon layer as claimed in claim 16, wherein the material of the substrate is metal, a mixture of metal and ceramic, or a mixture of metal and diamond.

20. The method of manufacturing a light emitting diode having a conductive diamond-like carbon layer as claimed in claim 14, wherein the material of the reflective layer is at least one selected from the group consisting of aluminum, silver, nickel (Ni), cobalt (Co), palladium (Pd), platinum (Pt), gold (Au), zinc (Zn), tin (Sn), antimony (Sb), lead (Pb), copper (Cu), copper-silver (CuAg) and nickel-silver (NiAg).

21. The method of manufacturing a light emitting diode having a conductive diamond-like carbon layer as claimed in claim 12, further comprising a step: roughening a surface of the second semiconductor epitaxial layer of the semiconductor epitaxial multilayer structure after removing the temporary substrate.

22. A chip-on-board package structure, comprising:
a circuit board; and
the light emitting diode having a diamond-like carbon layer as claimed in claim 1, that is electrically connected to the circuit board through the first electrode and the second electrode.

23. The chip-on-board package structure as claimed in claim 22, wherein the circuit board can include an insulating layer and a circuit substrate, and the material of the insulating layer is at least one selected from the group consisting of diamond-like carbon, aluminum oxide, ceramics and a diamond-containing epoxy resin.

24. The chip-on-board package structure as claimed in claim 23, wherein the circuit substrate is a metal sheet, a ceramic sheet or a silicon substrate.
